(19) United States
(12) Patent Application Publication
(10) Pub. No.: US 2023/0234169 A1
(43) Pub. Date: Jul. 27, 2023

(54) MANUFACTURING METHOD OF SINGLE-CRYSTAL SILICON SUBSTRATE

(71) Applicant: DISCO CORPORATION, Tokyo (JP)

(72) Inventor: Hayato IGA, Tokyo (JP)

(21) Appl. No.: 18/153,402

(22) Filed: Jan. 12, 2023

(30) Foreign Application Priority Data
Jan. 25, 2022 (JP) 2022-009070

(51) Int. Cl. B23K 26/53; B28D 5/00

(52) U.S. Cl. CPC B23K 26/53; B28D 5/0011

(57) ABSTRACT

There is provided a manufacturing method of a single-crystal silicon substrate by which the substrate is manufactured from a workpiece composed of single-crystal silicon manufactured in such a manner that a specific crystal plane included in the crystal planes {100} is exposed in each of a front surface and a back surface. The manufacturing method includes a separation layer forming step of forming separation layers including modified parts and cracks that extend from the modified parts inside the workpiece and a splitting-off step of splitting off the substrate from the workpiece with use of the separation layers as the point of origin after the separation layer forming step is executed. In the separation layer forming step, the separation layers are formed inside the workpiece composed of the single-crystal silicon by using a laser beam with such a wavelength as to be transmitted through the single-crystal silicon.

### BACKGROUND OF THE INVENTION

### Field of the Invention

The present invention relates to a manufacturing method of a single-crystal silicon substrate by which the substrate is manufactured from a workpiece composed of single-crystal silicon manufactured in such a manner that a specific crystal plane included in the crystal planes {100} is exposed in each of a front surface and a back surface.

### Description of the Related Art

In general, chips of a semiconductor device are manufactured by using a single-crystal silicon substrate (hereinafter, referred to also as “substrate” simply) with a circular disc shape. This substrate is cut out from an ingot composed of single-crystal silicon with a circular column shape (hereinafter, referred to also as “ingot” simply) by using a wire saw, for example (for example, refer to Japanese Patent Laid-open No. H09-262826).

### SUMMARY OF THE INVENTION

The cutting allowance when a substrate is cut out from an ingot by using a wire saw is approximately 300 μm, which is comparatively large. Further, minute recesses and protrusions are formed in a surface of the substrate thus cut out, and this substrate bends totally (warpage occurs in the substrate). Thus, in this substrate, the surface thereof needs to be planarized through executing lapping, etching, and/or polishing for the surface.

In this case, the amount of material of the single-crystal silicon used as the substrates finally is approximately ⅔ of the amount of material of the whole ingot. That is, approximately ⅓ of the amount of material of the whole ingot is discarded in the cutting-out of the substrates from the ingot and the planarization of the substrates. Thus, the productivity becomes low in a case of manufacturing the substrates by using the wire saw as above.

In view of this point, an object of the present invention is to provide a manufacturing method of a single-crystal silicon substrate with high productivity.

In accordance with an aspect of the present invention, there is provided a manufacturing method of a single-crystal silicon substrate by which the substrate is manufactured from a workpiece composed of single-crystal silicon manufactured in such a manner that a specific crystal plane included in crystal planes {100} is exposed in each of a front surface and a back surface. The manufacturing method includes a separation layer forming step of forming separation layers including modified parts and cracks that extend from the modified parts inside the workpiece and a splitting-off step of splitting off the substrate from the workpiece with use of the separation layers as a point of origin after the separation layer forming step is executed. The separation layer forming step has a first processing step for forming the separation layers in a plurality of first regions that each extend along a first direction that is parallel to the specific crystal plane and in which an angle formed with respect to a specific crystal orientation included in crystal orientations <100> is equal to or smaller than 5° and are separate from each other in a second direction that is parallel to the specific crystal plane and is orthogonal to the first direction and a second processing step for forming the separation layers in a plurality of second regions that each extend along the first direction and are separate from each other in the second direction after the first processing step is executed. Any of the plurality of second regions is positioned between a pair of first regions adjacent in the plurality of first regions. Any of the plurality of first regions is positioned between a pair of second regions adjacent in the plurality of second regions. The first processing step is executed by alternately repeating a first laser beam irradiation step of relatively moving the workpiece and a focal point of a laser beam with such a wavelength as to be transmitted through the single-crystal silicon along the first direction in a state in which the focal point is positioned to any of the plurality of first regions and a first indexing feed step of relatively moving a position at which the focal point is formed and the workpiece along the second direction. The second processing step is executed by alternately repeating a second laser beam irradiation step of relatively moving the focal point and the workpiece along the first direction in a state in which the focal point is positioned to any of the plurality of second regions and a second indexing feed step of relatively moving the position at which the focal point is formed and the workpiece along the second direction.

Preferably, the separation layer forming step has a third processing step for forming the separation layers sequentially from a region located at one end in the second direction toward a region located at the other end in the plurality of first regions and the plurality of second regions before the first processing step is executed. Further, the third processing step is executed by alternately repeating a third laser beam irradiation step of relatively moving the focal point and the workpiece along the first direction in a state in which the focal point is positioned to any of the plurality of first regions and the plurality of second regions and a third indexing feed step of relatively moving the position at which the focal point is formed and the workpiece along the second direction.

In the present invention, the separation layers are formed inside the workpiece composed of the single-crystal silicon by using the laser beam with such a wavelength as to be transmitted through the single-crystal silicon, and thereafter, the substrate is split off from the workpiece with use of these separation layers as the point of origin. This can improve the productivity of the single-crystal silicon substrate compared with the case of manufacturing the substrate from the workpiece by using a wire saw.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically illustrating one example of an ingot;

FIG. 2 is a top view schematically illustrating the one example of the ingot;

FIG. 3 is a flowchart schematically illustrating one example of a manufacturing method of a single-crystal silicon substrate;

FIG. 4 is a top view schematically illustrating plural regions included in the ingot;

FIG. 5 is a flowchart schematically illustrating one example of a separation layer forming step;

FIG. 6 is a diagram schematically illustrating one example of a laser processing apparatus;

FIG. 7 is a top view schematically illustrating a holding table that holds the ingot;

FIG. 8 is a flowchart schematically illustrating one example of a first processing step;

FIG. 9A is a top view schematically illustrating the state of one example of a first laser beam irradiation step;

FIG. 9B is a partially sectional side view schematically illustrating the state of the one example of the first laser beam irradiation step;

FIG. 10 is a sectional view schematically illustrating a separation layer formed inside the ingot in the first laser beam irradiation step;

FIG. 11 is a sectional view schematically illustrating the separation layer formed inside the ingot by executing the first laser beam irradiation step again;

FIG. 12 is a flowchart schematically illustrating one example of a second processing step;

FIG. 13 is a sectional view schematically illustrating the separation layer formed inside the ingot by executing the second laser beam irradiation step;

FIG. 14A is a partially sectional side view schematically illustrating the state of one example of a splitting-off step;

FIG. 14B is a partially sectional side view schematically illustrating the state of the one example of the splitting-off step;

FIG. 15 is a graph illustrating the widths of the separation layers formed inside a workpiece composed of single-crystal silicon when regions along different crystal orientations are irradiated with a laser beam;

FIG. 16 is a flowchart schematically illustrating another example of the separation layer forming step;

FIG. 17 is a flowchart schematically illustrating one example of a third processing step;

FIG. 18 is a sectional view schematically illustrating the separation layers formed inside the ingot by repeatedly executing a third laser beam irradiation step;

FIG. 19A is a partially sectional side view schematically illustrating another example of the splitting-off step;

FIG. 19B is a partially sectional side view schematically illustrating the other example of the splitting-off step;

FIG. 20A is a section photograph illustrating a separation layer formed in an ingot of Example 1;

FIG. 20B is a section photograph illustrating the separation layer formed in the ingot of Example 1;

FIG. 20C is a section photograph illustrating the separation layer formed in the ingot of Example 1;

FIG. 21A is a section photograph illustrating a separation layer formed in an ingot of Example 2;

FIG. 21B is a section photograph illustrating the separation layer formed in the ingot of Example 2;

FIG. 21C is a section photograph illustrating the separation layer formed in the ingot of Example 2;

FIG. 22A is a graph illustrating the distribution of a component in the thickness direction of the ingot regarding 20 cracks formed in the ingot of Example 1; and

FIG. 22B is a graph illustrating the distribution of the component in the thickness direction of the ingot regarding 20 cracks formed in the ingot of Example 2.

### DETAILED DESCRIPTION OF THE PREFERRED EMBODIMENT

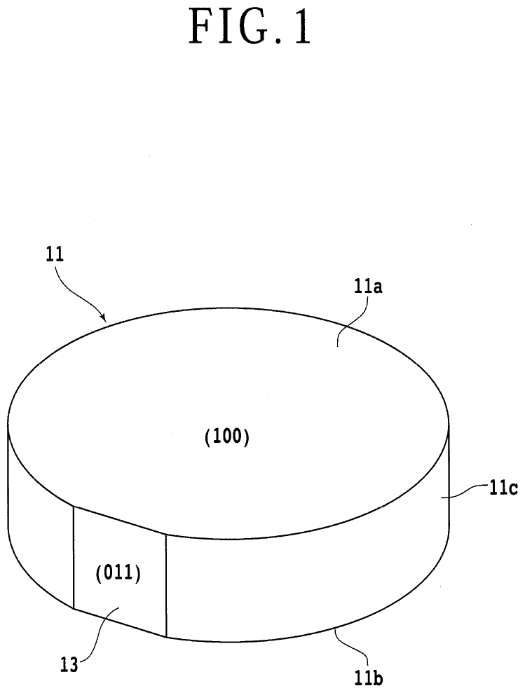

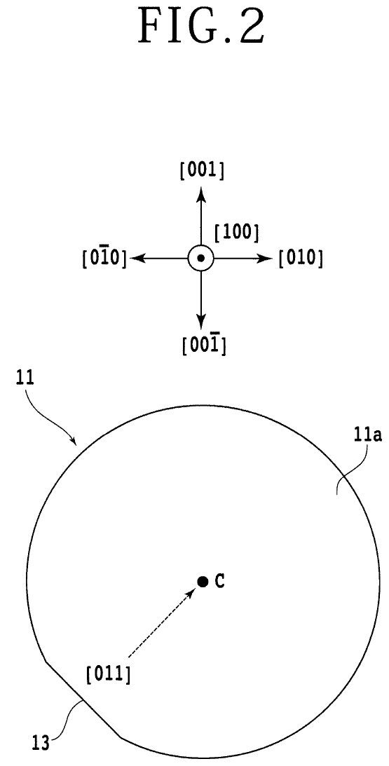

An embodiment of the present invention will be described with reference to the accompanying drawings. FIG. 1 is a perspective view schematically illustrating one example of an ingot. FIG. 2 is a top view schematically illustrating the one example of the ingot. In FIG. 1, crystal planes of single-crystal silicon exposed in planes included in this ingot are also illustrated. Further, in FIG. 2, crystal orientations of the single-crystal silicon that configures this ingot are also illustrated.

An ingot 11 illustrated in FIG. 1 and FIG. 2 is composed of circular columnar single-crystal silicon in which a specific crystal plane included in the crystal planes {100} (here, defined as crystal plane (100) for convenience) is exposed in each of a front surface 11a and a back surface 11b. That is, the ingot 11 is composed of circular columnar single-crystal silicon in which the perpendicular line (crystal axis) to each of the front surface 11a and the back surface 11b is along the crystal orientation [100].

The ingot 11 is manufactured in such a manner that the crystal plane (100) is exposed in each of the front surface 11a and the back surface 11b. However, a surface slightly inclined from the crystal plane (100) may be exposed in each of the front surface 11a and the back surface 11b due to a processing error in the manufacturing, or the like.

Specifically, a surface in which the angle formed with respect to the crystal plane (100) is equal to or smaller than 1° may be exposed in each of the front surface 11a and the back surface 11b of the ingot 11. That is, the crystal axis of the ingot 11 may be along a direction in which the angle formed with respect to the crystal orientation [100] is equal to or smaller than 1°.

Further, an orientation flat 13 is formed in a side surface 11c of the ingot 11 and a center C of the ingot 11 is located in a specific crystal orientation included in the crystal orientations <110> (here, defined as a crystal orientation [011] for convenience) as viewed from the orientation flat 13. That is, the crystal plane (011) of the single-crystal silicon is exposed in the orientation flat 13.

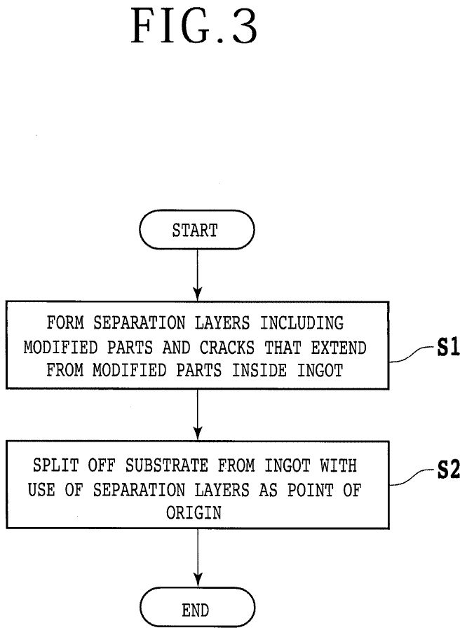

FIG. 3 is a flowchart schematically illustrating one example of a manufacturing method of a single-crystal silicon substrate by which a substrate is manufactured from the ingot 11 that becomes a workpiece. In this method, first, separation layers including modified parts and cracks that extend from the modified parts are formed inside the ingot 11 (separation layer forming step: S1).

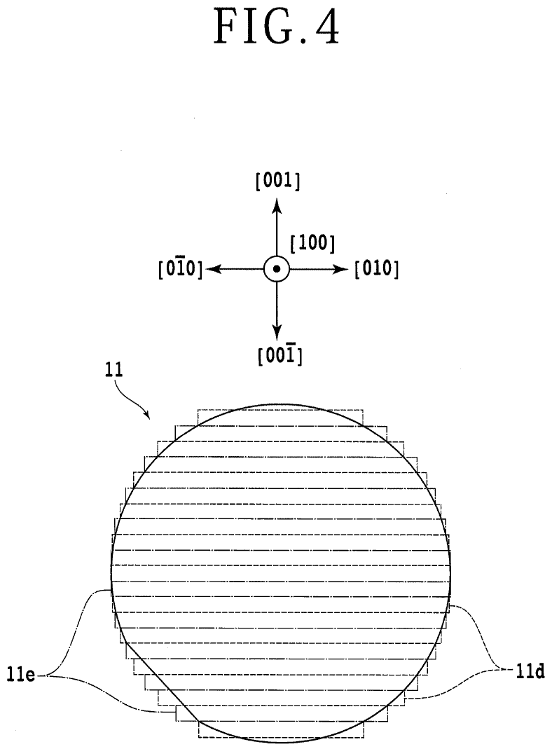

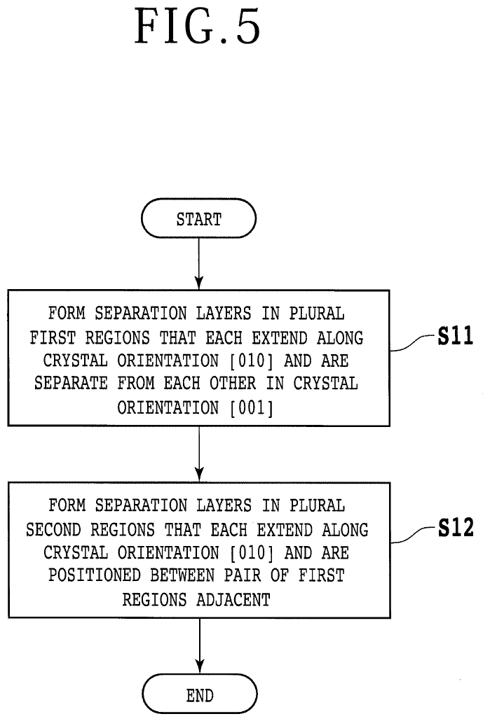

In this separation layer forming step (S1), the separation layers are formed sequentially for plural regions included in the ingot 11. FIG. 4 is a top view schematically illustrating the plural regions included in the ingot 11. Further, FIG. 5 is a flowchart schematically illustrating one example of the separation layer forming step (S1).

In this separation layer forming step (S1), first, the separation layers are formed in plural first regions 11d that each extend along the crystal orientation [010] and are separate from each other in the crystal orientation [001] (first processing step: S11).

Then, after the completion of the first processing step (S11), the separation layers are formed in plural second regions 11e that each extend along the crystal orientation [010] and are located between a pair of the first regions 11d adjacent (second processing step: S12).

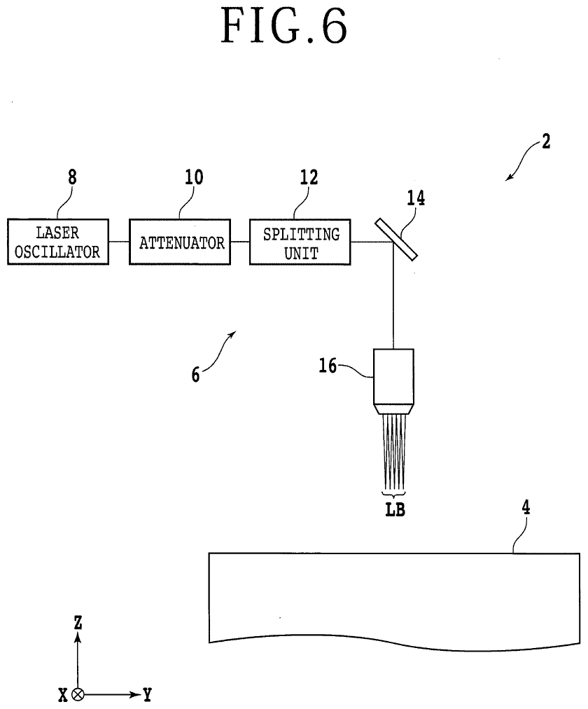

Moreover, in the separation layer forming step (S1), the separation layers are formed inside the ingot 11 by using a laser processing apparatus. FIG. 6 is a diagram schematically illustrating one example of the laser processing apparatus used when the separation layers are formed inside the ingot 11.

An X-axis direction (first direction) and a Y-axis direction (second direction) illustrated in FIG. 6 are directions orthogonal to each other on the horizontal plane. Further, a Z-axis direction is the direction (vertical direction) orthogonal to each of the X-axis direction and the Y-axis direction. In addition, in FIG. 6, part of constituent elements of the laser processing apparatus is illustrated by functional blocks.

A laser processing apparatus 2 illustrated in FIG. 6 has a holding table 4 with a circular disc shape. The holding table 4 has a circular upper surface (holding surface) parallel to the X-axis direction and the Y-axis direction, for example. Further, the holding table 4 has a circular disc-shaped porous plate (not illustrated) having an upper surface exposed in this holding surface.

Moreover, this porous plate communicates with a suction source (not illustrated) such as an ejector through a flow path made inside the holding table 4, and so forth. Further, when this suction source operates, a negative pressure is generated in a space in the vicinity of the holding surface of the holding table 4. This can hold the ingot 11 placed on the holding surface by the holding table 4, for example.

Moreover, a laser beam irradiation unit 6 is disposed over the holding table 4. The laser beam irradiation unit 6 has a laser oscillator 8. For example, the laser oscillator 8 has neodymium-doped yttrium aluminum garnet (Nd:YAG) or the like as a laser medium and emits a pulsed laser beam LB with such a wavelength (for example, 1064 nm) as to be transmitted through the material that configures the ingot 11 (single-crystal silicon).

The laser beam LB is supplied to a splitting unit 12 after its output power is adjusted in an attenuator 10. The splitting unit 12 includes a spatial light modulator and/or diffractive optical element (DOE) including a liquid crystal phase control element generally referred to as liquid crystal on silicon (LCoS), and so forth.

Further, the splitting unit 12 splits the laser beam LB in such a manner that the laser beam LB with which the holding surface side of the holding table 4 is irradiated from an irradiation head 16 to be described later forms plural focal points that line up along the Y-axis direction.

The laser beam LB split in the splitting unit 12 is reflected by a mirror 14 and is guided to the irradiation head 16. A collecting lens (not illustrated) that focuses the laser beam LB and so forth are housed in the irradiation head 16. Further, the holding surface side of the holding table 4 is irradiated with the laser beam LB focused by this collecting lens.

Moreover, the irradiation head 16 of the laser beam irradiation unit 6 is coupled to a movement mechanism (not illustrated). For example, this movement mechanism includes a ball screw and so forth and moves the irradiation head 16 along the X-axis direction, the Y-axis direction, and/or the Z-axis direction.

Furthermore, in the laser processing apparatus 2, the position (coordinates) in the X-axis direction, the Y-axis direction, and the Z-axis direction regarding the focal points of the laser beam LB with which the holding surface side of the holding table 4 is irradiated from the irradiation head 16 can be adjusted by operating this movement mechanism.

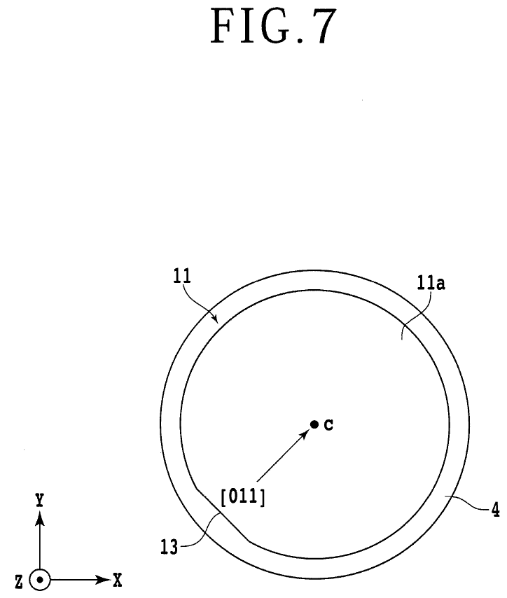

When the separation layer forming step (S1) is executed in the laser processing apparatus 2, first, the holding table 4 holds the ingot 11 in a state in which the front surface 11a is oriented upward. FIG. 7 is a top view schematically illustrating the holding table 4 that holds the ingot 11.

For example, the ingot 11 is held by the holding table 4 in a state in which the angle formed by the direction from the orientation flat 13 toward the center C of the ingot 11 (crystal orientation [011]) with respect to each of the X-axis direction and the Y-axis direction is 45°.

That is, the ingot 11 is held by the holding table 4 in a state in which the crystal orientation [010] is parallel to the X-axis direction and the crystal orientation [001] is parallel to the Y-axis direction, for example. After the ingot 11 is held by the holding table 4 in this manner, the first processing step (S11) is executed.

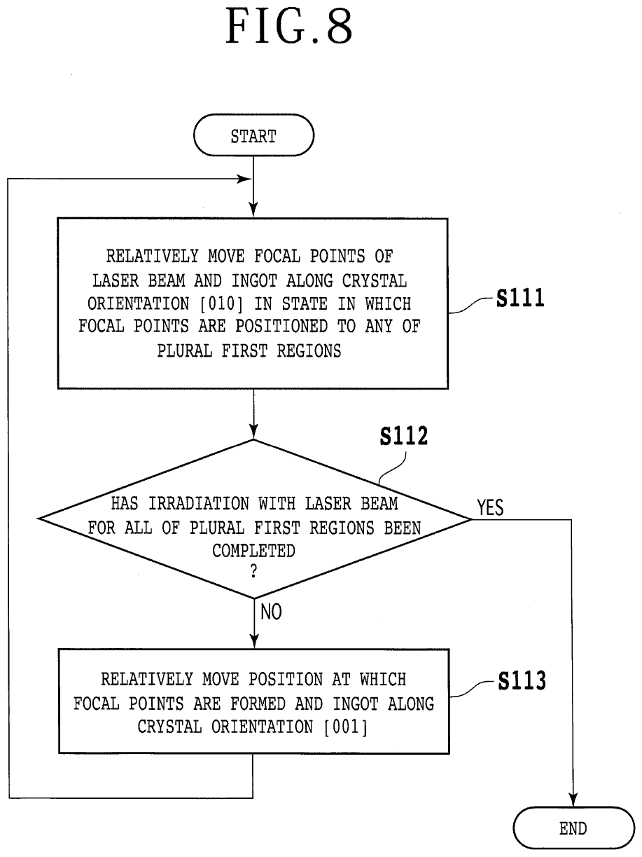

FIG. 8 is a flowchart schematically illustrating one example of the first processing step (S11). In this first processing step (S11), first, the focal points of the laser beam LB and the ingot 11 are relatively moved along the X-axis direction (crystal orientation [010]) in a state in which the focal points are positioned to any of the plural first regions 11d (first laser beam irradiation step: S111).

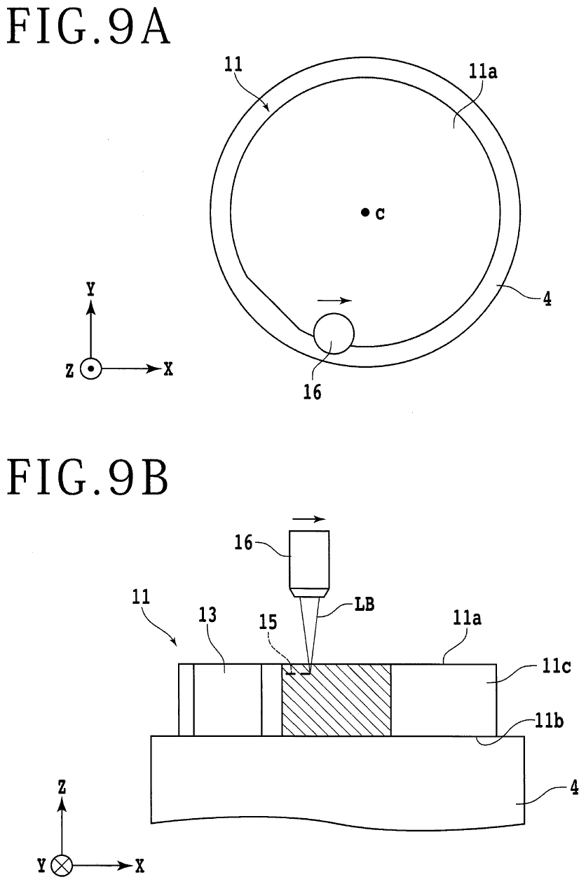

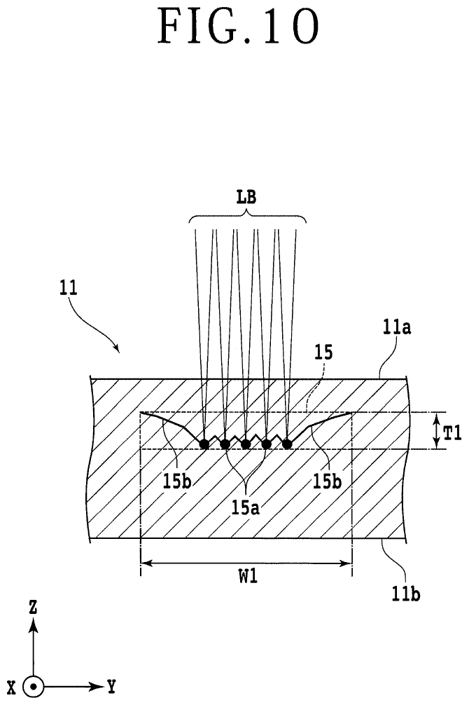

FIG. 9A is a top view schematically illustrating the state of one example of the first laser beam irradiation step (S111). FIG. 9B is a partially sectional side view schematically illustrating the state of the one example of the first laser beam irradiation step (S111). Further, FIG. 10 is a sectional view schematically illustrating the separation layer formed inside the ingot 11 in the first laser beam irradiation step (S111).

In this first laser beam irradiation step (S111), for example, the separation layer is formed first in the first region 11d located at one end in the Y-axis direction (crystal orientation [001]) in the plural first regions 11d. Specifically, first, the irradiation head 16 of the laser beam irradiation unit 6 is positioned to cause the first region 11d to be positioned in the X-axis direction as viewed from the irradiation head 16 in plan view.

Subsequently, the irradiation head 16 is raised and lowered to cause the plural focal points formed by focusing the respective laser beams LB resulting from splitting to be positioned to a height corresponding to the inside of the ingot 11.

Next, while the laser beam LB is emitted from the irradiation head 16 toward the holding table 4, the irradiation head 16 is moved to pass from one end to the other end of the ingot 11 in the X-axis direction (crystal orientation [010]) in plan view (see FIG. 9A and FIG. 9B).

Thereby, the plural focal points and the ingot 11 relatively move along the X-axis direction (crystal orientation [010]) in a state in which the plural focal points are positioned inside the ingot 11. The laser beam LB is split and focused to form plural (for example, five) focal points that line up at equal intervals in the Y-axis direction (crystal orientation) [001]) (see FIG. 10).

Further, inside the ingot 11, a modified part 15a arising from disordering of the crystal structure of the single-crystal silicon is formed around each of the plural focal points. In addition, when the modified parts 15a are formed inside the ingot 11, the volume of the ingot 11 expands, and an internal stress is generated in the ingot 11.

This internal stress is alleviated through extension of cracks 15b from the modified parts 15a. As a result, a separation layer 15 including the plural modified parts 15a and the cracks 15b that develop from each of the plural modified parts 15a is formed inside the ingot 11.

Here, in general, the single-crystal silicon is cleaved along a specific crystal plane included in the crystal planes {111} most easily and is cleaved along a specific crystal plane included in the crystal planes {110} second most easily.

Thus, for example, when the modified part is formed along a specific crystal orientation included in the crystal orientation <110> (for example, crystal orientation [011]) of the single-crystal silicon that configures the ingot, there occur many cracks that extend along a specific crystal plane included in the crystal plane {111} from this modified part.

On the other hand, when plural modified parts are formed in a region along a specific crystal orientation included in the crystal orientations <100> of the single-crystal silicon in such a manner as to line up along the direction orthogonal to the direction in which this region extends in plan view, there occur many cracks that extend along crystal planes parallel to the direction in which the region extends in crystal planes {N10} (N is a natural number equal to or smaller than 10) from each of these plural modified parts.

For example, when plural modified parts 15a are formed in a region along the crystal orientation [010] in such a manner as to line up at equal intervals in the crystal orientation [001] as described above, there occur many cracks that extend along crystal planes parallel to the crystal orientation [010] in crystal planes {N10} (N is a natural number equal to or smaller than 10) from each of these plural modified parts 15a.

Specifically, when the plural modified parts 15a are formed as above, cracks easily extend in the following crystal planes.

$$( 101 ) , ( 201 ) , ( 301 ) , ( 401 ) , ( 501 ) , ( 601 ) , ( 701 ) , ( 801 ) , ( 901 ) , ( \underline{10} 01 ) \qquad [ Math . 1 ]$$

$$( \overline{1} 01 ) , ( \overline{2} 01 ) , ( \overline{3} 01 ) , ( \overline{4} 01 ) , ( \overline{5} 01 ) , ( \overline{6} 01 ) , ( \overline{7} 01 ) , ( \overline{8} 01 ) , ( \overline{9} 01 ) , ( \underline{\overline{10}} 01 ) \qquad [ Math . 2 ]$$

Further, the angles formed by the crystal plane (100) exposed in the front surface 11a and the back surface 11b of the ingot 11 with respect to crystal planes parallel to the crystal orientation [010] in crystal planes {N10} are equal to or smaller than 45°. On the other hand, the angle formed by the crystal plane (100) with respect to a specific crystal plane included in the crystal plane {111} is approximately 54.7°.

Thus, in a case in which the ingot 11 is irradiated with the laser beam LB along the crystal orientation [010] (former case), the separation layer 15 tends to have a wide width and be thin compared with a case in which irradiation with the laser beam LB is executed along the crystal orientation [011] (latter case). That is, the value of the ratio of the width (W1) and the thickness (T1) (W1/T1) of the separation layer 15 illustrated in FIG. 10 becomes larger in the former case than that in the latter case.

Further, in a situation in which irradiation with the laser beam LB for all of the plural first regions 11d has not been completed (step (S112): NO), the position at which the focal points are formed and the ingot 11 are relatively moved along the Y-axis direction (crystal orientation [001]) (first indexing feed step: S113).

In this first indexing feed step (S113), for example, the irradiation head 16 is moved along the Y-axis direction (crystal orientation [001]) until the irradiation head 16 is positioned in the X-axis direction (crystal orientation [010]) as viewed from the first region 11d in which the separation layer 15 has not been formed and that is adjacent to the first region 11d in which the separation layer 15 has been already formed.

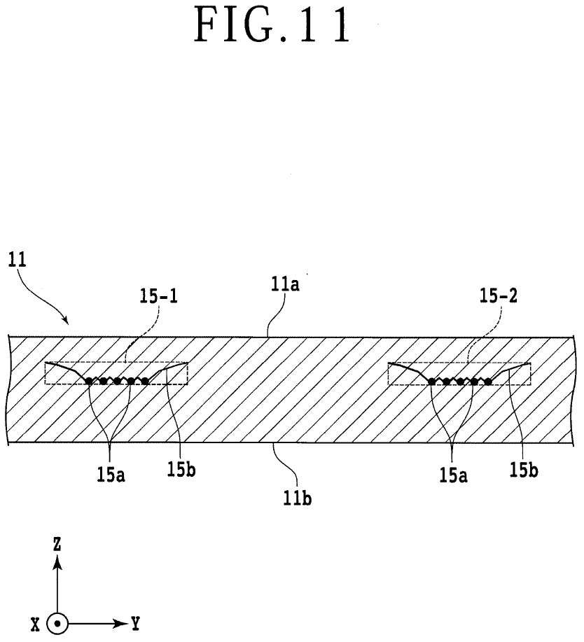

Subsequently, the above-described first laser beam irradiation step (S111) is executed again. When the first laser beam irradiation step (S111) is executed again as above, as illustrated in FIG. 11, the separation layer 15 (separation layer 15-2) that is parallel to the already-formed separation layer 15 (separation layer 15-1) and is separate from the separation layer 15-1 in the Y-axis direction (crystal orientation [001]) is formed inside the ingot 11.

Moreover, the first indexing feed step (S113) and the first laser beam irradiation step (S111) are alternately executed repeatedly until the separation layers 15 are formed in all of the plural first regions 11d included in the ingot 11. Then, when the separation layers 15 have been formed in all of the plural first regions 11d (step (S112): YES), the second processing step (S12) is executed.

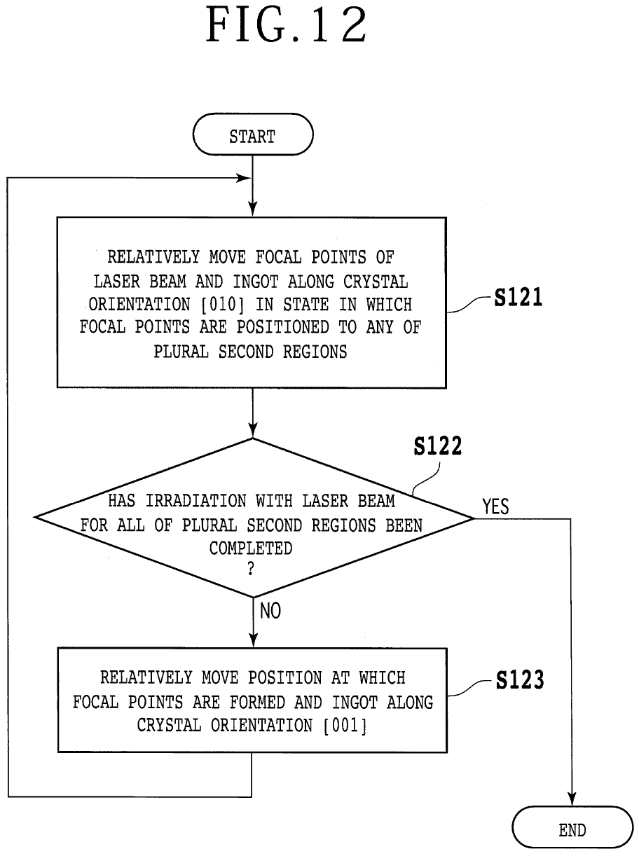

FIG. 12 is a flowchart schematically illustrating one example of the second processing step (S12). In this second processing step (S12), first, the focal points of the laser beam LB and the ingot 11 are relatively moved along the X-axis direction (crystal orientation [010]) in a state in which the focal points are positioned to any of the plural second regions 11e (second laser beam irradiation step: S121).

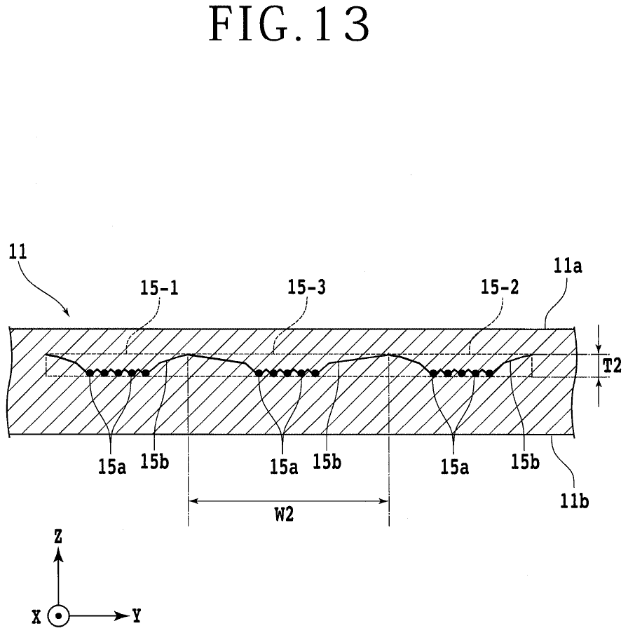

The second laser beam irradiation step (S121) is executed similarly to the above-described first laser beam irradiation step (S111), and therefore, detailed description thereof is omitted. When the second laser beam irradiation step (S121) is executed, as illustrated in FIG. 13, the separation layer 15 (separation layer 15-3) that is parallel to the already-formed separation layers 15 (separation layers 15-1 and 15-2) and is positioned between them is formed inside the ingot 11.

Here, the cracks 15b that extend from the modified parts 15a included in the separation layer 15-3 (former cracks) tend to extend to connect to the cracks 15b included in the existing separation layers 15-1 and 15-2 (latter cracks).

Thus, in the former cracks, the component along the Y-axis direction (crystal orientation [001]) tends to become larger than the component along the Z-axis direction (crystal orientation [100]) compared with the latter cracks.

In this case, the separation layer 15-3 has a wide width and is thin compared with the separation layers 15-1 and 15-2. That is, the value of the ratio of the width (W2) and the thickness (T2) (W2/T2) of the separation layer 15-3 illustrated in FIG. 13 becomes larger than the value of the ratio of the width (W1) and the thickness (T1) (W1/T1) of the separation layer 15 (separation layers 15-1 and 15-2) illustrated in FIG. 10.

Further, in a situation in which irradiation with the laser beam LB for all of the plural second regions 11e has not been completed (step (S122): NO), the position at which the focal points are formed and the ingot 11 are relatively moved along the Y-axis direction (crystal orientation [001]) (second indexing feed step: S123).

In this second indexing feed step (S123), for example, the irradiation head 16 is moved along the Y-axis direction (crystal orientation [001]) until the irradiation head 16 is positioned in the X-axis direction (crystal orientation [010]) as viewed from the second region 11e in which the separation layer 15 has not been formed and that is adjacent to the second region 11e in which the separation layer 15 has been already formed.

Subsequently, the above-described second laser beam irradiation step (S121) is executed again. Moreover, the second indexing feed step (S123) and the second laser beam irradiation step (S121) are alternately executed repeatedly until the separation layers 15 are formed in all of the plural second regions 11e included in the ingot 11.

Then, when the separation layers 15 have been formed in all of the plural second regions 11e (step (S122): YES), a substrate is split off from the ingot 11 with use of the separation layers 15 as the point of origin (splitting-off step: S2).

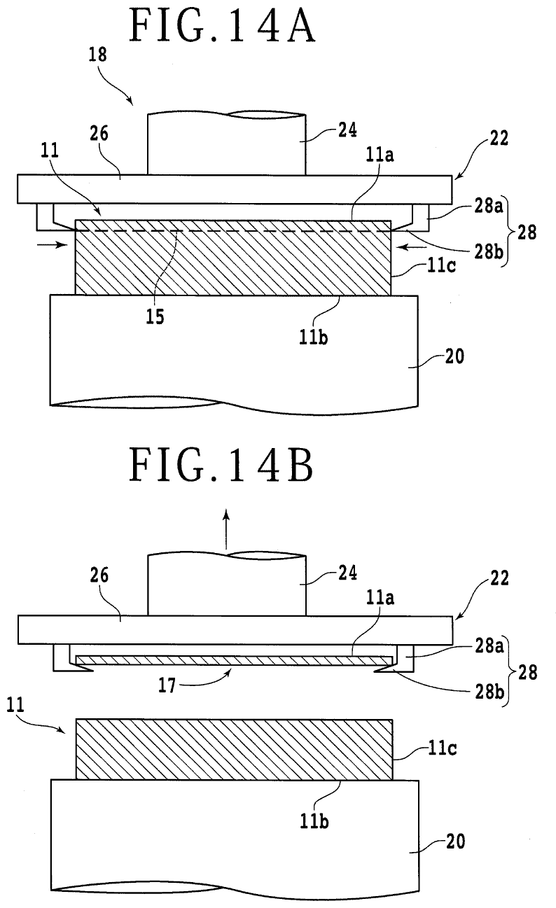

Each of FIG. 14A and FIG. 14B is a partially sectional side view schematically illustrating the state of one example of the splitting-off step (S2). For example, this splitting-off step (S2) is executed in a splitting-off apparatus 18 illustrated in FIG. 14A and FIG. 14B. The splitting-off apparatus 18 has a holding table 20 that holds the ingot 11 in which the separation layers 15 have been formed.

The holding table 20 has a circular upper surface (holding surface) and a porous plate (not illustrated) is exposed in this holding surface. Moreover, this porous plate communicates with a suction source (not illustrated) such as a vacuum pump through a flow path made inside the holding table 20, and so forth. Further, when this suction source operates, a negative pressure is generated in a space in the vicinity of the holding surface of the holding table 20.

Moreover, a splitting-off unit 22 is disposed over the holding table 20. The splitting-off unit 22 has a support component 24 with a circular column shape. To an upper part of the support component 24, a raising-lowering mechanism (not illustrated) of a ball screw system and a rotational drive source such as a motor are coupled, for example.

Further, the splitting-off unit 22 rises and lowers by operating this raising-lowering mechanism. In addition, by operating this rotational drive source, the support component 24 rotates with a straight line that passes through the center of the support component 24 and is along the direction perpendicular to the holding surface of the holding table 20 being the rotation axis.

Moreover, a lower end part of the support component 24 is fixed to the center of an upper part of a base 26 with a circular disc shape. On the lower side of an outer circumferential region of the base 26, plural movable components 28 are disposed at substantially equal intervals along the circumferential direction of the base 26. These movable components 28 each have a plate-shaped erected part 28a that extends downward from the lower surface of the base 26.

Upper end parts of these erected parts 28a are coupled to an actuator such as an air cylinder incorporated in the base 26 and the movable components 28 move along the radial direction of the base 26 by operating this actuator. Furthermore, plate-shaped wedge parts 28b that extend toward the center of the base 26 and in which the thickness becomes thinner toward the tip are disposed on the inner side surfaces of lower end parts of these erected parts 28a.

In the splitting-off apparatus 18, the splitting-off step (S2) is executed in the following order, for example. Specifically, first, the ingot 11 is placed on the holding table 20 in such a manner that the center of the back surface 11b of the ingot 11 in which the separation layers 15 have been formed is made to correspond with the center of the holding surface of the holding table 20.

Subsequently, the suction source communicating with the porous plate exposed in this holding surface is operated to cause the ingot 11 to be held by the holding table 20. Next, the actuator is operated to position each of the plural movable components 28 to the outside in the radial direction of the base 26.

Subsequently, the raising-lowering mechanism is operated to position the tip of the wedge part 28b of each of the plural movable components 28 to a height corresponding to the separation layers 15 formed inside the ingot 11. Next, the actuator is operated to cause the wedge parts 28b to be driven into the side surface 11c of the ingot 11 (see FIG. 14A).

Subsequently, the rotational drive source is operated to rotate the wedge parts 28b driven into the side surface 11c of the ingot 11. Next, the raising-lowering mechanism is operated to raise the wedge parts 28b (see FIG. 14B).

By raising the wedge parts 28b after driving the wedge parts 28b into the side surface 11c of the ingot 11 and rotating them as above, the cracks 15b included in the separation layers 15 further extend. As a result, the side of the front surface 11a and the side of the back surface 11b of the ingot 11 are split off. That is, a substrate 17 is manufactured from the ingot 11 with use of the separation layers 15 as the point of origin.

The wedge parts 28b do not need to be rotated in a case in which the side of the front surface 11a and the side of the back surface 11b of the ingot 11 are split off at the timing when the wedge parts 28b are driven into the side surface 11c of the ingot 11. Further, the wedge parts 28b that rotate may be driven into the side surface 11c of the ingot 11 through simultaneously operating the actuator and the rotational drive source.

In the above-described manufacturing method of a single-crystal silicon substrate, the separation layers 15 are formed inside the ingot 11 by using the laser beam LB with such a wavelength as to be transmitted through single-crystal silicon, and thereafter the substrate 17 is split off from the ingot 11 with use of these separation layers 15 as the point of origin.

Due to this, compared with the case of manufacturing the substrate 17 from the ingot 11 by using a wire saw, the amount of material discarded when the substrate 17 is manufactured from the ingot 11 can be reduced and the productivity of the substrate 17 can be improved.

Moreover, in this method, the plural modified parts 15a are formed in a region along the crystal orientation [010] (X-axis direction) in such a manner as to line up along the crystal orientation [001] (Y-axis direction). In this case, there occur many cracks that extend along crystal planes parallel to the crystal orientation [010] in crystal planes {N10} (N is a natural number equal to or smaller than 10) from each of the plural modified parts 15a.

This allows the separation layers 15 to have a wide width and be thin compared with a case in which the ingot 11 is irradiated with the laser beam LB along the crystal orientation [011]. As a result, the amount of material discarded when the substrate 17 is manufactured from the ingot 11 can be further reduced, and the productivity of the substrate 17 can be further improved.

Further, in this method, after the separation layers 15 (separation layers 15-1 and 15-2) are formed in the plural first regions 11d included in the ingot 11, the separation layers 15 (separation layer 15-3) are formed in the plural second regions 11e. Here, in the separation layer 15-3, the cracks 15b in which the component along the Y-axis direction (crystal orientation) [001]) is larger than the cracks 15b included in the separation layers 15-1 and 15-2 tend to be formed.

That is, in this case, the value of the ratio of the width (W2) and the thickness (T2) (W2/T2) of the separation layer 15-3 becomes large compared with the value of the ratio of the width (W1) and the thickness (T1) (W1/T1) of the separation layers 15-1 and 15-2. As a result, the amount of material discarded when the substrate 17 is manufactured from the ingot 11 can be further reduced, and the productivity of the substrate 17 can be further improved.

The above-described manufacturing method of a single-crystal silicon substrate is one aspect of the present invention, and the present invention is not limited to the above-described method. For example, the ingot used in order to manufacture the substrate in the present invention is not limited to the ingot 11 illustrated in FIG. 1, FIG. 2, and so forth.

Specifically, in the present invention, the substrate may be manufactured from an ingot in which a notch is formed in the side surface. Alternatively, in the present invention, the substrate may be manufactured from an ingot in which neither an orientation flat nor a notch is formed in the side surface.

Further, the structure of the laser processing apparatus used in the present invention is not limited to the structure of the above-described laser processing apparatus 2. For example, the present invention may be carried out by using a laser processing apparatus equipped with a movement mechanism that moves the holding table 4 along each of the X-axis direction, the Y-axis direction, and/or the Z-axis direction.

That is, in the present invention, it is sufficient that the holding table 4 that holds the ingot 11 and the irradiation head 16 of the laser beam irradiation unit 6 that executes irradiation with the laser beam LB can relatively move along each of the X-axis direction, the Y-axis direction, and the Z-axis direction, and there is no limit on the structure for this purpose.

Moreover, the plural first regions and the plural second regions included in the ingot 11 irradiated with the laser beam LB in the separation layer forming step (S1) of the present invention are not limited to the plural first regions 11d and the plural second regions 11e illustrated in FIG. 4. For example, in the present invention, each of the plural first regions may be positioned between a pair of the second regions adjacent.

Furthermore, the plural first regions and the plural second regions included in the ingot 11 irradiated with the laser beam LB in the separation layer forming step (S1) of the present invention are not limited to regions along the crystal orientation [010]. For example, in the present invention, regions along the crystal orientation [001] may be irradiated with the laser beam LB.

When the ingot 11 is irradiated with the laser beam LB as above, cracks easily extend in the following crystal planes.

$$( 110 ) , ( 210 ) , ( 310 ) , ( 410 ) , ( 510 , ( 610 ) , ( 710 ) , ( 810 ) , ( 910 ) , ( \underline{10} 10 ) \qquad [ Math . 3 ]$$

$$( \overline{1} 10 ) , ( \overline{2} 10 ) , ( \overline{3} 10 ) , ( \overline{4} 10 ) , ( \overline{5} 10 , ( \overline{6} 10 ) , ( \overline{7} 10 ) , ( \overline{8} 10 ) , ( \overline{9} 10 ) , ( \underline{\overline{10}} 10 ) \qquad [ Math . 4 ]$$

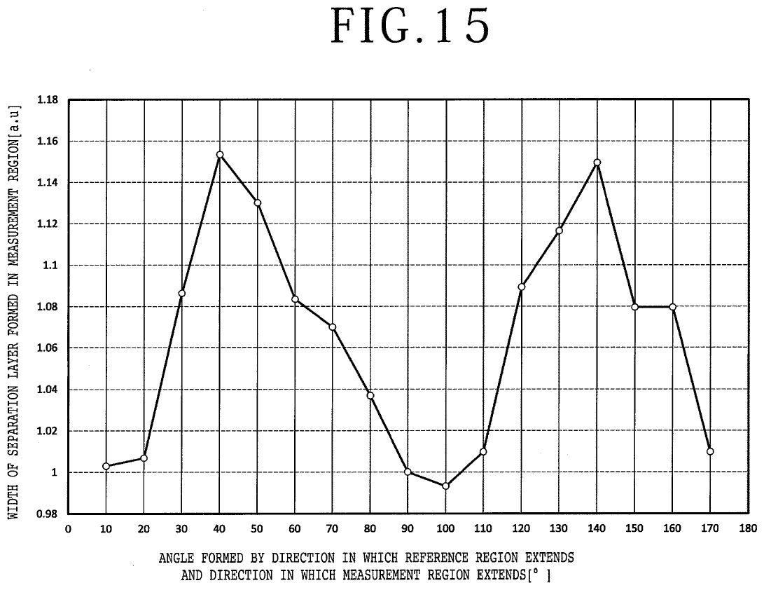

Moreover, in the present invention, a region along a direction slightly inclined from the crystal orientation [010] or the crystal orientation [001] in plan view may be irradiated with the laser beam LB. Regarding this point, description will be made with reference to FIG. 15.

FIG. 15 is a graph illustrating the widths (width (W1) illustrated in FIG. 10) of the separation layers formed inside a workpiece composed of single-crystal silicon when regions along different crystal orientations are irradiated with the laser beam LB. The abscissa axis of this graph indicates the angle formed by the direction in which a region orthogonal to the crystal orientation [011] (reference region) extends and the direction in which a region that becomes a measurement subject (measurement region) extends in plan view.

That is, when the value of the abscissa axis of this graph is 45°, the region along the crystal orientation [001] is the measurement subject. Similarly, when the value of the abscissa axis of this graph is 135°, the region along the crystal orientation [010] is the measurement subject.

Further, the ordinate axis of this graph indicates the value obtained when the width of the separation layer formed in the measurement region by irradiating the measurement region with the laser beam LB is divided by the width of the separation layer formed in the reference region by irradiating the reference region with the laser beam LB.

As illustrated in FIG. 15, the width of the separation layer becomes wide when the angle formed by the direction in which the reference region extends and the direction in which the measurement region extends is 40° to 50° or 130° to 140°. That is, the width of the separation layer becomes wide not only when the region along the crystal orientation [001] or the crystal orientation [010] is irradiated with the laser beam LB but also when the region along a direction in which the angle formed with respect to either of these crystal orientations is equal to or smaller than 5° is irradiated with the laser beam LB.

Thus, in the separation layer forming step (S1) of the present invention, the region along a direction inclined from the crystal orientation [001] or the crystal orientation [010] by at most 5° in plan view may be irradiated with the laser beam LB.

That is, in the separation layer forming step (S1) of the present invention, irradiation with the laser beam LB may be executed for the region along a direction (first direction) that is parallel to the crystal plane exposed in each of the front surface 11a and the back surface 11b of the ingot 11 (here, crystal plane (100)) in specific crystal planes included in the crystal planes {100} and in which the angle formed with respect to a specific crystal orientation (here, crystal orientation [001] or crystal orientation [010]) included in the crystal orientations <100> is equal to or smaller than 5°.

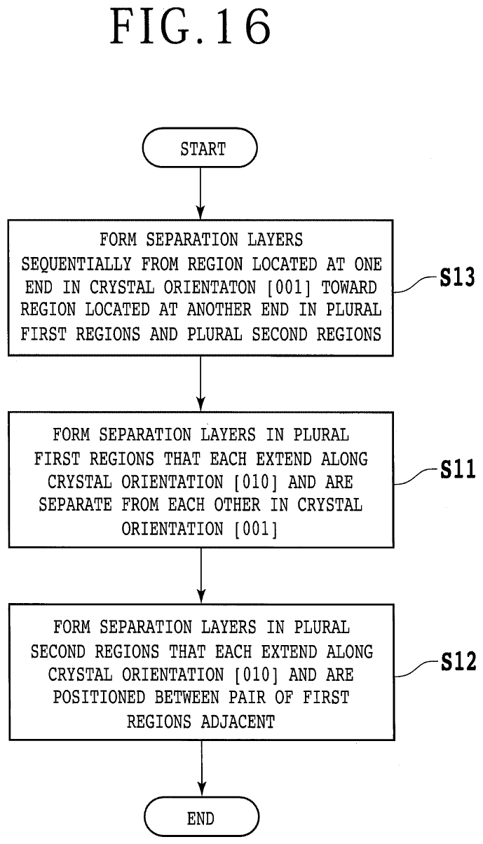

Moreover, in the separation layer forming step (S1) of the present invention, irradiation with the laser beam LB for each of the plural first regions 11d and the plural second regions 11e included in the ingot 11 may be executed plural times. FIG. 16 is a flowchart schematically illustrating one example of such a separation layer forming step (S1).

In the separation layer forming step (S1) illustrated in FIG. 16, before the first processing step (S11), the separation layers 15 are formed sequentially from the region (first region 11d or second region 11e) located at one end in the Y-axis direction (crystal orientation [001]) toward the region (first region 11d or second region 11e) located at the other end in the plural first regions 11d and the plural second regions 11e (third processing step: S13).

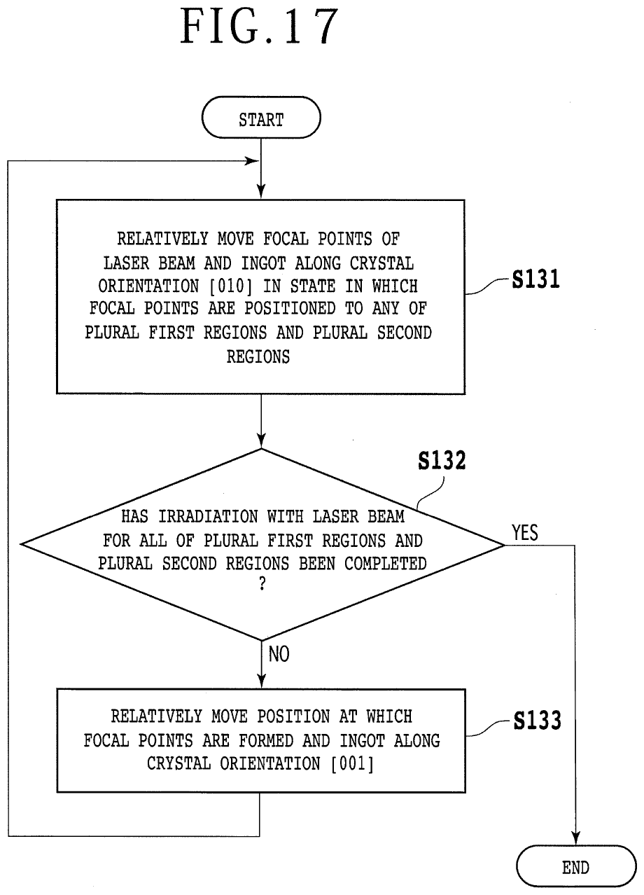

FIG. 17 is a flowchart schematically illustrating one example of the third processing step (S13). In this third processing step (S13), first, the focal points of the laser beam LB and the ingot 11 are relatively moved along the X-axis direction (crystal orientation [010]) in a state in which the focal points are positioned to any of the plural first regions 11d and the plural second regions 11e (third laser beam irradiation step: S131).

The third laser beam irradiation step (S131) is executed similarly to the above-described first laser beam irradiation step (S111) and second laser beam irradiation step (S121), and therefore, detailed description thereof is omitted.

Further, in a situation in which irradiation with the laser beam LB for all of the plural first regions 11d and the plural second regions 11e has not been completed (step (S132): NO), the position at which the focal points are formed and the ingot 11 are relatively moved along the Y-axis direction (crystal orientation [001]) (third indexing feed step: S133).

The third indexing feed step (S133) is executed similarly to the above-described first indexing feed step (S113) and second indexing feed step (S123), and therefore, detailed description thereof is omitted.

Subsequently, the above-described third laser beam irradiation step (S131) is executed again. Moreover, the third indexing feed step (S133) and the third laser beam irradiation step (S131) are alternately executed repeatedly until the separation layers 15 are formed in all of the plural first regions 11d and the plural second regions 11e included in the ingot 11.

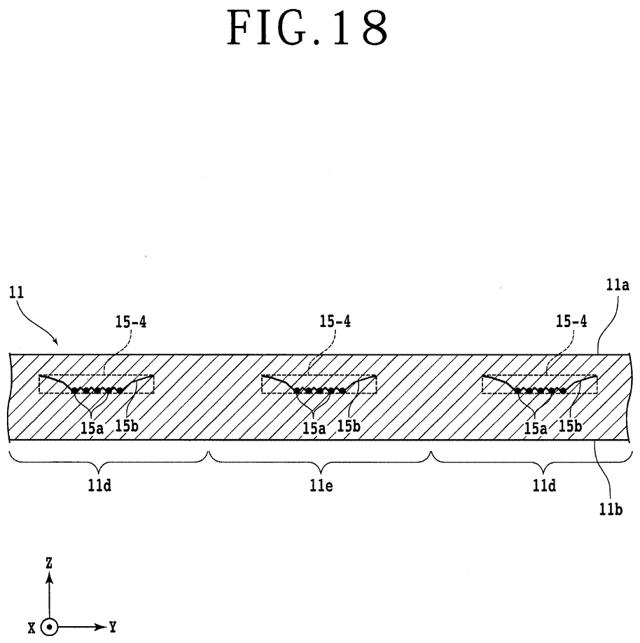

When the third indexing feed step (S133) and the third laser beam irradiation step (S131) are alternately executed repeatedly, for example, as illustrated in FIG. 18, plural separation layers 15-4 separate from each other in the Y-axis direction (crystal orientation [001]) can be formed inside the ingot 11.

Then, when the separation layers 15 have been formed in all of the plural first regions 11d and the plural second regions 11e (step (S132): YES), the above-described first processing step (S11) and second processing step (S12) are sequentially executed.

When the plural first regions 11d and the plural second regions 11e in which the separation layers 15-4 have been already formed are irradiated with the laser beam LB again as above, the density of each of the modified part 15a and the crack 15b included in the already-formed separation layers 15-4 increases.

Due to this, splitting-off of the substrate 17 from the ingot 11 in the splitting-off step (S2) becomes easy. Moreover, in this case, the cracks 15b included in the separation layers 15-4 further extend, and the width of the separation layers 15-4 becomes wider.

Thus, in this case, it is possible to extend the relative movement distance (index) between the ingot 11 and the irradiation head 16 of the laser beam irradiation unit 6 in each of the first indexing feed step (S113), the second indexing feed step (S123), and the third indexing feed step (S133).

Further, in the present invention, forming the separation layers 15 in the whole region of the inside of the ingot 11 in the separation layer forming step (S1) is not an indispensable characteristic. For example, in a case in which the cracks 15b extend to a region in the vicinity of the side surface 11c of the ingot 11 in the splitting-off step (S2), the separation layer 15 does not need to be formed in part or the whole of the region in the vicinity of the side surface 11c of the ingot 11 in the separation layer forming step (S1).

Moreover, the splitting-off step (S2) of the present invention may be executed by using an apparatus other than the splitting-off apparatus 18 illustrated in FIG. 14A and FIG. 14B. For example, in the splitting-off step (S2) of the present invention, the substrate 17 may be split off from the ingot 11 by sucking the side of the front surface 11a of the ingot 11.

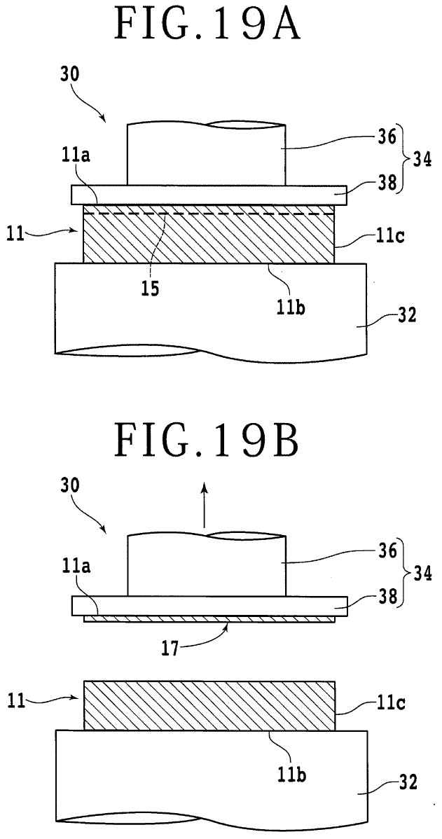

Each of FIG. 19A and FIG. 19B is a partially sectional side view schematically illustrating one example of the splitting-off step (S2) executed in this manner. A splitting-off apparatus 30 illustrated in FIG. 19A and FIG. 19B has a holding table 32 that holds the ingot 11 in which the separation layers 15 have been formed.

The holding table 32 has a circular upper surface (holding surface) and a porous plate (not illustrated) is exposed in this holding surface. Moreover, this porous plate communicates with a suction source (not illustrated) such as a vacuum pump through a flow path made inside the holding table 32, and so forth. Thus, when this suction source operates, a negative pressure is generated in a space in the vicinity of the holding surface of the holding table 32.

Further, a splitting-off unit 34 is disposed over the holding table 32. The splitting-off unit 34 has a support component 36 with a circular column shape. To an upper part of the support component 36, a raising-lowering mechanism (not illustrated) of a ball screw system is coupled, for example. The splitting-off unit 34 rises and lowers by operating this raising-lowering mechanism.

Moreover, a lower end part of the support component 36 is fixed to the center of an upper part of a suction plate 38 with a circular disc shape. Plural suction ports are formed in the lower surface of the suction plate 38, and each of the plural suction ports communicates with a suction source (not illustrated) such as a vacuum pump through a flow path made inside the suction plate 38, and so forth. Thus, when this suction source operates, a negative pressure is generated in a space in the vicinity of the lower surface of the suction plate 38.

In the splitting-off apparatus 30, the splitting-off step (S2) is executed in the following order, for example. Specifically, first, the ingot 11 is placed on the holding table 32 in such a manner that the center of the back surface 11b of the ingot 11 in which the separation layers 15 have been formed is made to correspond with the center of the holding surface of the holding table 32.

Subsequently, the suction source communicating with the porous plate exposed in this holding surface is operated to cause the ingot 11 to be held by the holding table 32. Next, the raising-lowering mechanism is operated to lower the splitting-off unit 34 in such a manner as to bring the lower surface of the suction plate 38 into contact with the front surface 11a of the ingot 11.

Subsequently, the suction source communicating with the plural suction ports formed in the suction plate 38 is operated to cause the side of the front surface 11a of the ingot 11 to be sucked through the plural suction ports (see FIG. 19A). Next, the raising-lowering mechanism is operated, and the splitting-off unit 34 is raised to separate the suction plate 38 from the holding table 32 (see FIG. 19B).

At this time, an upward force acts on the side of the front surface 11a of the ingot 11 for which the side of the front surface 11a is sucked through the plural suction ports formed in the suction plate 38. As a result, the cracks 15b included in the separation layers 15 further extend, and the side of the front surface 11a and the side of the back surface 11b of the ingot 11 are split off. That is, the substrate 17 is manufactured from the ingot 11 with use of the separation layers 15 as the point of origin.

Further, in the splitting-off (S2) of the present invention, ultrasonic may be given to the side of the front surface 11a of the ingot 11 prior to the splitting-off between the side of the front surface 11a and the side of the back surface 11b of the ingot 11. In this case, the cracks 15b included in the separation layers 15 further extend, and therefore, the splitting-off between the side of the front surface 11a and the side of the back surface 11b of the ingot 11 becomes easy.

Moreover, in the present invention, the front surface 11a of the ingot 11 may be planarized by grinding or polishing (planarization step) prior to the separation layer forming step (S1). For example, this planarization may be executed when plural substrates are manufactured from the ingot 11.

Specifically, when splitting-off in the ingot 11 is caused at the separation layers 15 and the substrate 17 is manufactured, recesses and protrusions that reflect the distribution of the modified parts 15a and the cracks 15b included in the separation layers 15 are formed in the newly-exposed surface of the ingot 11. Thus, in a case of manufacturing a new substrate from the ingot 11, it is preferable to planarize the surface of the ingot 11 prior to the separation layer forming step (S1).

This can suppress diffuse reflection of the laser beam LB with which the ingot 11 is irradiated in the separation layer forming step (S1) at the surface of the ingot 11. Similarly, in the present invention, the surface on the side of the separation layers 15 in the substrate 17 split off from the ingot 11 may be planarized by grinding or polishing.

Further, in the present invention, a bare wafer composed of single-crystal silicon manufactured in such a manner that a specific crystal plane included in the crystal planes {100} is exposed in each of a front surface and a back surface may be employed as a workpiece to manufacture a substrate.

This bare wafer has a thickness that is two times to five times of that of the substrate to be manufactured, for example. Moreover, this bare wafer is manufactured by being split off from the ingot 11 by a method similar to the above-described method, for example. In this case, it is also possible to represent that the substrate is manufactured by repeating the above-described method twice.

Further, in the present invention, a device wafer manufactured by forming semiconductor devices on one surface of this bare wafer may be employed as a workpiece to manufacture a substrate. Besides, structures, methods, and so forth according to the above-described embodiment can be carried out with appropriate changes without departing from the range of the object of the present invention.

### EXAMPLES

Ingots of Examples 1 and 2 composed of single-crystal silicon were prepared. Then, separation layers were formed inside the ingot of Example 1 by the same procedure as the separation layer forming step (S1) illustrated in FIG. 16. That is, irradiation with a laser beam for each of plural first regions and plural second regions included in the ingot of Example 1 was executed twice.

The power of the laser beam used in each of the first laser beam irradiation step (S111), the second laser beam irradiation step (S121), and the third laser beam irradiation step (S131) at this time was 2.0 to 5.0 W, and the number of split laser beams was 8.

Further, the index in the first indexing feed step (S113) and the second indexing feed step (S123) at this time was 1140 μm and the index in the third indexing feed step (S133) at this time was 570 μm.

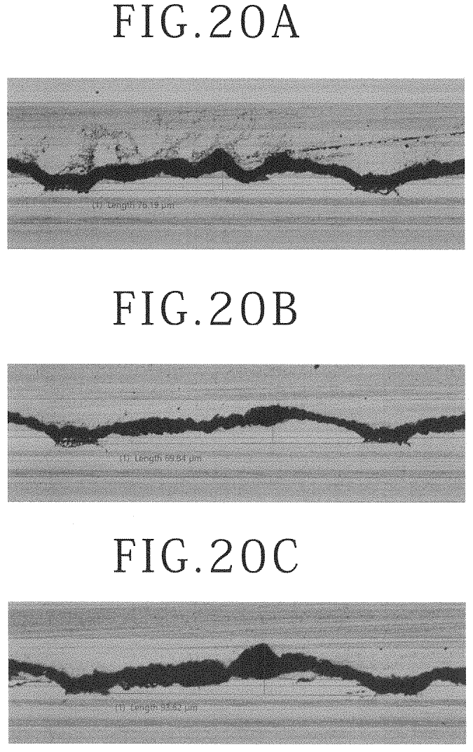

Each of FIG. 20A, FIG. 20B, and FIG. 20C is a section photograph illustrating the separation layer formed in the ingot of Example 1. It proved that cracks included in the separation layers linearly extended to connect adjacent modified parts in a case of forming the separation layers inside the ingot by the same procedure as the separation layer forming step (S1) illustrated in FIG. 16.

Moreover, separation layers were formed inside the ingot of Example 2 by repeating the third processing step (S13) illustrated in FIG. 16 twice. That is, as with the ingot of Example 1, irradiation with the laser beam for each of plural first regions and plural second regions included in the ingot of Example 2 was executed twice.

The power of the laser beam used in the third laser beam irradiation step (S13) at this time was 2.0 to 5.0 W, and the number of split laser beams was 8. Further, the index in the third indexing feed step (S133) at this time was 560 μm.

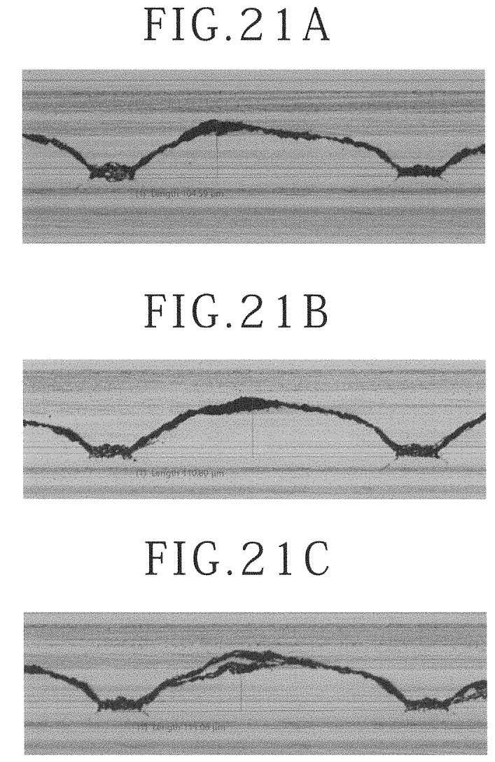

Each of FIG. 21A, FIG. 21B, and FIG. 21C is a section photograph illustrating the separation layer formed in the ingot of Example 2. It proved that cracks included in the separation layers extended in an arch form to connect adjacent modified parts in a case of forming the separation layers inside the ingot by repeating the third processing step (S131) illustrated in FIG. 16 twice.

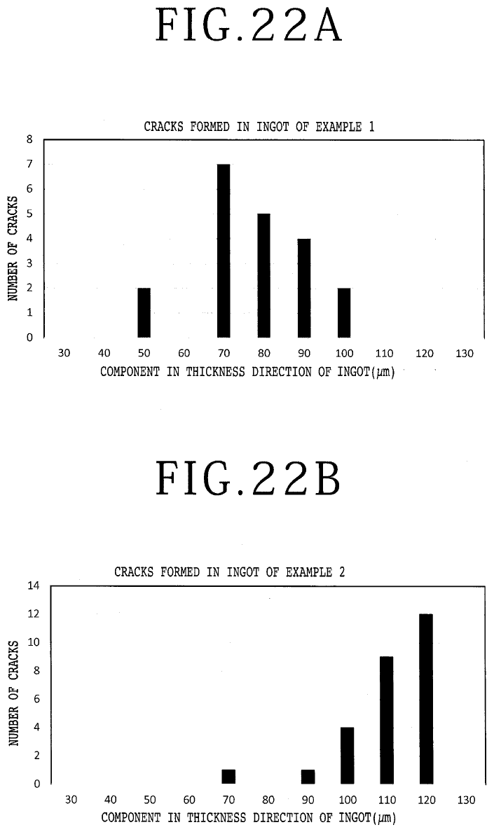

FIG. 22A is a graph illustrating the distribution of the component in the thickness direction of the ingot (length in the upward-downward direction in FIG. 20A and so forth) regarding 20 cracks formed in the ingot of Example 1. FIG. 22B is a graph illustrating the distribution of the component in the thickness direction of the ingot (length in the upward-downward direction in FIG. 21A and so forth) regarding 20 cracks formed in the ingot of Example 2.

Further, the following table 1 is a table indicating the average value (Avg) and the maximum value (Max) of the component of the 20 cracks formed in the ingot of Example 1 and the average value (Avg) and the maximum value (Max) of the component of the 20 cracks formed in the ingot of Example 2.

TABLE 1

| | Avg (μm) | Max (μm) |
|---|---|---|
| Cracks formed in ingot of Example 1 | 73.3 | 93.6 |
| Cracks formed in ingot of Example 2 | 101.8 | 117.2 |

It proved that, in the cracks included in the separation layers formed in the ingot of Example 1, the component in the thickness direction of the ingot became small compared with the cracks included in the separation layers formed in the ingot of Example 2.

Thus, it proved that, in a case of forming the separation layers in the ingot by the same procedure as the separation layer forming step (S1) illustrated in FIG. 16, the amount of material discarded when a substrate was manufactured from this ingot could be reduced and the productivity of the substrate could be improved compared with the case of forming the separation layers inside the ingot of Example 2 by repeating the third processing step (S13) illustrated in FIG. 16 twice.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A manufacturing method of a single-crystal silicon substrate by which the substrate is manufactured from a workpiece composed of single-crystal silicon manufactured in such a manner that a specific crystal plane included in crystal planes {100} is exposed in each of a front surface and a back surface, the manufacturing method comprising:
a separation layer forming step of forming separation layers including modified parts and cracks that extend from the modified parts inside the workpiece; and
a splitting-off step of splitting off the substrate from the workpiece with use of the separation layers as a point of origin after the separation layer forming step is executed, wherein
the separation layer forming step has
a first processing step for forming the separation layers in a plurality of first regions that each extend along a first direction that is parallel to the specific crystal plane and in which an angle formed with respect to a specific crystal orientation included in crystal orientations <100> is equal to or smaller than 5° and are separate from each other in a second direction that is parallel to the specific crystal plane and is orthogonal to the first direction, and
a second processing step for forming the separation layers in a plurality of second regions that each extend along the first direction and are separate from each other in the second direction after the first processing step is executed,
any of the plurality of second regions is positioned between a pair of first regions adjacent in the plurality of first regions,
any of the plurality of first regions is positioned between a pair of second regions adjacent in the plurality of second regions,
the first processing step is executed by alternately repeating
a first laser beam irradiation step of relatively moving the workpiece and a focal point of a laser beam with such a wavelength as to be transmitted through the single-crystal silicon along the first direction in a state in which the focal point is positioned to any of the plurality of first regions, and
a first indexing feed step of relatively moving a position at which the focal point is formed and the workpiece along the second direction, and
the second processing step is executed by alternately repeating
a second laser beam irradiation step of relatively moving the focal point and the workpiece along the first direction in a state in which the focal point is positioned to any of the plurality of second regions, and
a second indexing feed step of relatively moving the position at which the focal point is formed and the workpiece along the second direction.

2. The manufacturing method of a single-crystal silicon substrate according to claim 1, wherein
the separation layer forming step has a third processing step for forming the separation layers sequentially from a region located at one end in the second direction toward a region located at another end in the plurality of first regions and the plurality of second regions before the first processing step is executed, and
the third processing step is executed by alternately repeating
a third laser beam irradiation step of relatively moving the focal point and the workpiece along the first direction in a state in which the focal point is positioned to any of the plurality of first regions and the plurality of second regions, and
a third indexing feed step of relatively moving the position at which the focal point is formed and the workpiece along the second direction.
